(19) United States
(12) Patent Application Publication
(10) Pub. No.: US 2025/0362442 A1
(43) Pub. Date: Nov. 27, 2025

(54) SYSTEMS AND METHODS FOR MULTI-LAYER NANOSTRUCTURED POLARIZATION OPTICS

(71) Applicant: Samsung Electronics Co., Ltd., Suwon-si (KR)

(72) Inventors: Radwanul Hasan SIDDIQUE, Monrovia, CA (US); Mahsa TORFEH, Los Angeles, CA (US); Haeri Park HANANIA, Sierra Madre, CA (US)

(21) Appl. No.: 18/884,094

(22) Filed: Sep. 12, 2024

Related U.S. Application Data
(60) Provisional application No. 63/650,391, filed on May 21, 2024.

(51) Int. Cl. G02B 5/30; G02B 1/00; G02B 27/28

(52) U.S. Cl. CPC G02B 5/3025; G02B 1/002; G02B 27/283

(57) ABSTRACT

Provided are systems, methods, and apparatuses for systems and methods for multi-layer nanostructured polarization optics. In one or more examples, the systems, devices, and methods include splitting unpolarized light into a first beam of light of a first polarized state and a second beam of light of a second polarized state; deflecting the first beam of light; deflecting and converting a polarization state of the second beam of light; and combining the deflected first beam of light with and the deflected and converted second beam of light.

### CROSS-REFERENCE TO RELATED APPLICATIONS

This application claims the benefit of U.S. Provisional Patent Application Ser. No. 63/650,391 filed May 21, 2024, which is incorporated by reference herein for all purposes.

### TECHNICAL FIELD

The disclosure relates generally to image systems. More specifically, the subject matter disclosed herein relates to a multifunctional polarization filter that includes nanostructures that change the phase, amplitude and/or polarization of incident light based on aspects of the nanostructures.

### BACKGROUND

The present background section is intended to provide context only, and the disclosure of any concept in this section does not constitute an admission that said concept is prior art.

Polarization can include a property of transverse waves that specifies a geometrical orientation of oscillations. In a transverse wave, the direction of the oscillation is perpendicular to the direction of motion of the wave. The oscillations can be in a vertical direction, horizontal direction, or at any angle perpendicular to the direction of propagation. Transverse waves that exhibit polarization can include electromagnetic waves such as light and radio waves, gravitational waves, and transverse sound waves (shear waves) in solids. A polarizer can include an optical filter that allows light waves of a given polarization to pass through while blocking light waves with other polarizations.

### SUMMARY

In various embodiments, the systems and methods described herein include systems, methods, and apparatuses for systems and methods for multi-layer nanostructured polarization optics. In some aspects, the systems and methods described herein relate to a polarization filter including: a beamsplitter metalens to split incident light that is unpolarized into a beam of light of a first polarized state and a beam of light of a second polarized state; a first metalens to deflect the beam of light of the first polarized state received from the beamsplitter metalens; a second metalens adjacent to the first metalens, the second metalens to deflect the beam of light of the second polarized state received from the beamsplitter metalens and to convert a polarization of the beam of light of the second polarized state; and a beam receiving element to receive a combination of the deflected light of the first polarized state from the first metalens and the deflected converted light of the second polarized state from the second metalens, the beam receiving element including at least one of a photodetector, a curved lens, a metalens, a nanostructure, or a mirror.

In some aspects, the techniques described herein relate to a polarization filter, wherein the second metalens is configured to convert the beam of light of the second polarized state from the second polarized state to the first polarized state.

In some aspects, the techniques described herein relate to a polarization filter, wherein at least one nanostructure element of the beamsplitter metalens induces a phase shift within a range of 0 degrees to 270 degrees.

In some aspects, the techniques described herein relate to a polarization filter, wherein: a first element of the beamsplitter metalens induces a first phase shift on a portion of the incident light that is in the first polarized state, and the first element of the beamsplitter metalens induces a second phase shift different from the first phase shift on a portion of the incident light that is in the second polarized state.

In some aspects, the techniques described herein relate to a polarization filter, wherein: a second element of the beamsplitter metalens induces a third phase shift on the portion of the incident light that is in the first polarized state, the second element of the beamsplitter metalens induces a fourth phase shift different from the third phase shift on the portion of the incident light that is in the second polarized state, the first phase shift is different from the third phase shift and the fourth phase shift, and the second phase shift is different from the third phase shift and the fourth phase shift.

In some aspects, the techniques described herein relate to a polarization filter, wherein at least one of the beamsplitter metalens, the first metalens, or the second metalens include repeating groups of nanostructure elements.

In some aspects, the techniques described herein relate to a polarization filter, wherein a width of a group of nanostructure elements of the repeating groups of nanostructure elements is within a range of one-fourth to three times a wavelength of the incident light.

In some aspects, the techniques described herein relate to a polarization filter, wherein a distance from the beamsplitter metalens to at least one of the first metalens or the second metalens is within a range of one times to two times a width of the beamsplitter metalens.

In some aspects, the techniques described herein relate to a polarization filter, wherein a distance from the beamsplitter metalens to the beam receiving element is within a range of one time to four times a width of the beamsplitter metalens.

In some aspects, the techniques described herein relate to a polarization filter, wherein: a nanostructure element of the first metalens corresponds to a nanostructure element of the second metalens, and an orientation of the nanostructure element of the second metalens is tilted with respect to an orientation of the nanostructure element of the first metalens.

In some aspects, the techniques described herein relate to a polarization filter, wherein at least one of the beamsplitter metalens, the first metalens, or the second metalens include at least one of silicon dioxide, silicon nitride, or a complementary metal-oxide-semiconductor.

In some aspects, the techniques described herein relate to a polarization filter, wherein: at least one of the beamsplitter metalens, the first metalens, or the second metalens are deposited on a substrate layer, and a refractive index of the beamsplitter metalens, the first metalens, or the second metalens is higher than a refractive index of the substrate layer.

In some aspects, the techniques described herein relate to a polarization filter, wherein a nanostructure element of at least one of the beamsplitter metalens, the first metalens, or the second metalens may be configured with at least one of a circle, an oval, a square, a rectangle, a triangle, a pillar, a hole, or an anisotropic geometry.

In some aspects, the techniques described herein relate to a polarization filter, wherein the first polarized state and the second polarized state include, respectively, a first linear polarization and a second linear polarization, or a first circular polarization and a second circular polarization.

In some aspects, the techniques described herein relate to a polarization filter, wherein: the beamsplitter metalens is configured to cause a first steering on the beam of light of the first polarized state and cause a second steering on the beam of light of the second polarized state, the first metalens is configured to cause a third steering on the beam of light of the first polarized state, and the first metalens is configured to cause a fourth steering on the beam of light of the second polarized state.

In some aspects, the techniques described herein relate to a polarization filter, wherein: the first steering includes at least one of focusing, bending, or passing the beam of light of the first polarized state, the second steering includes at least one of focusing, bending, or passing the beam of light of the second polarized state, the third steering includes at least one of focusing, bending, or passing the beam of light of the first polarized state, and the fourth steering includes at least one of focusing, bending, or passing the beam of light of the second polarized state.

In some aspects, the techniques described herein relate to a method including: splitting, via a beamsplitter metalens, incident light that is unpolarized into a beam of light of a first polarized state and a beam of light of a second polarized state; deflecting, via a first metalens, the beam of light of the first polarized state received from the beamsplitter metalens; deflecting, via a second metalens adjacent to the first metalens, the beam of light of the second polarized state received from the beamsplitter metalens; converting, via the second metalens, a polarization of the beam of light of the second polarized state in conjunction with the deflecting via the second metalens; and receiving, via a beam receiving element, a combination of the deflected light of the first polarized state from the first metalens and the deflected converted light of the second polarized state from the second metalens, the beam receiving element including at least one of a photodetector, a curved lens, a metalens, a nanostructure, or a mirror.

In some aspects, the techniques described herein relate to a method, wherein the second metalens is configured to convert the beam of light of the second polarized state from the second polarized state to the first polarized state.

In some aspects, the techniques described herein relate to a polarization sensor, including: a beamsplitter metalens to split incident light that is unpolarized into a beam of light of a first polarized state and a beam of light of a second polarized state; a first metalens to deflect the beam of light of the first polarized state received from the beamsplitter metalens; a second metalens adjacent to the first metalens, the second metalens to deflect the beam of light of the second polarized state received from the beamsplitter metalens and to convert a polarization of the beam of light of the second polarized state; and a photodetector to detect a combination of the deflected light of the first polarized state from the first metalens and the deflected converted light of the second polarized state from the second metalens.

In some aspects, the techniques described herein relate to a polarization sensor, wherein the second metalens is configured to convert the beam of light of the second polarized state from the second polarized state to the first polarized state.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The systems and methods described herein provide multiple advantages and benefits. For example, the systems and methods improve the efficiency of polarization optics and light sources beyond contemporary theoretical capping limits (e.g., the systems and methods provide greater than 50% efficiency). The systems and methods are significantly more compact than other systems and provide a relatively thin and lightweight design. Also, the systems and methods are compatible with Complementary Metal-Oxide-Semiconductor (CMOS) systems, enabling the systems and methods to be implemented in on-chip applications and/or off-chip applications. Also, the systems and methods reduce and/or minimize power losses associated with polarization optics and filters, thus improving energy efficiency of a given system that implements the systems and methods described herein.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIG. 1 illustrates an example system in accordance with one or more implementations as described herein.

FIG. 2 illustrates an example system in accordance with one or more implementations as described herein.

FIG. 3 illustrates an example system in accordance with one or more implementations as described herein.

FIG. 4 illustrates an example metalens system in accordance with one or more implementations as described herein.

FIG. 5 illustrates an example metalens in accordance with one or more implementations as described herein.

FIG. 6 illustrates an example metalens in accordance with one or more implementations as described herein.

FIG. 7 illustrates an example of a metalens in accordance with one or more implementations as described herein.

FIG. 8 depicts a flow diagram illustrating an example method associated with the disclosed systems, in accordance with example implementations described herein.

FIG. 9 depicts a flow diagram illustrating an example method associated with the disclosed systems, in accordance with example implementations described herein.

FIG. 10 illustrates an example system in accordance with one or more implementations as described herein.

FIG. 11 illustrates an example system in accordance with one or more implementations as described herein.

FIG. 12 illustrates an example system in accordance with one or more implementations as described herein.

FIG. 13 illustrates an example system in accordance with one or more implementations as described herein.

FIG. 14 depicts a flow diagram illustrating an example method associated with the disclosed systems, in accordance with example implementations described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), crasable programmable read-only memory (EPROM), electrically crasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

In the description provided herein, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hard-wired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

An electromagnetic wave such as light may include a coupled oscillating electric field and magnetic field that are perpendicular to each other. The polarization of electromagnetic waves can refer to the direction of the electric field. In linear polarization, the fields may oscillate in a single direction. In circular or elliptical polarization, the fields may rotate at a constant rate in a plane as the wave travels, either in the right-hand or in the left-hand direction (e.g., clockwise, counter-clockwise).

Polarization can include a property of light that indicates the geometrical orientation of the oscillations, or vibrations, of the electromagnetic (EM) fields of the light. The EM vibrations may be directed to a specific direction using a polarizer or a polarizing filter. The general polarization of light may be in the horizontal, or x direction, or in the vertical, or y direction, with a phase o between the x and y axes. By determining the amplitude of electric field in, for example, x and y directions and the relative phase between the x and y direction, a full Stokes polarization state of the light may be determined.

When a linear polarization filter is added to a light source, it can filter at least 50% of the light, making such a system relatively inefficient. Thus, there is a need to devise a linear polarizer filter and/or circular polarizer filter with nearly 100% efficiency using metaphotonics. Some systems have split unpolarized light into paths using a polarizing beam splitter. For example, some systems may rotate light into circular polarization, then recombine the split beams to form a linear polarized beam. However, since the angle of linear polarization may be random and time varying, such systems may not be useful for cross-polarization based sensing, and may not provide an on-chip or compact solution. To overcome such issues, systems and methods are described herein for designing a relatively high efficiency polarization filter for polarization imaging and sensing systems including light sources, optics and detectors.

The systems and methods described herein improve on previous methods in several ways. The systems and methods improve the efficiency of polarization optics and light sources beyond capping limits of other systems (e.g., the systems and methods described herein provide greater than 50% efficiency). The systems and methods also provide a relatively compact, thin, and lightweight design. The systems and methods described herein may be complementary metal oxide semiconductor (CMOS) compatible, enabling the systems and methods to be implemented in on-chip applications and/or off-chip applications. The systems and methods reduce the power losses associated with polarization optics and filters.

Linear polarization may occur when an electric field of light is confined to a single plane along its propagation direction. Polarizers can be configured to provide some form of polarization of light. For example, a linear polarizer may polarize light in the p-polarization or the s-polarization. P-polarization and s-polarization are two types of linear polarization states associated with reflection and transmission of light. P-polarization (e.g., 0° polarization) may be perpendicular to s-polarization (e.g., 90° polarization). The terms come from the German words parallel (p) and senkrecht(s), senkrecht being German for perpendicular. The electric field of p-polarized light may be parallel to the plane of incidence, while the electric field of s-polarized light may be perpendicular to the plane of incidence. Linear polarizers can be used in various applications, such as glare reduction, camera filters, sunglasses, machine vision systems, etc.

The subject matter disclosed herein, in some embodiments, provides a multifunctional linear polarization filter that includes various mechanism to achieve a filter efficiency exceeding capping limits of other systems (e.g., the systems and methods described herein provide greater than 50% efficiency). The systems and methods may refer to linear polarization filter as one example of the systems and methods described herein. However, reference to linear polarization filter includes polarization filters for linear polarization and/or circular polarization (e.g., linear polarization filters and/or circular polarization filters).

The various mechanisms of the systems and methods may include at least one of a polarization splitter, a half wave phase retarder and various lenses/mirrors, multilayer nanostructured meta-surfaces for polarization splitting, and/or half wave retardation and lensing. The polarizer splitter may be configured to split unpolarized light into two different polarized lights. In some embodiments, the dimensions of the nanostructures include a first width and a second width that is perpendicular to the first width.

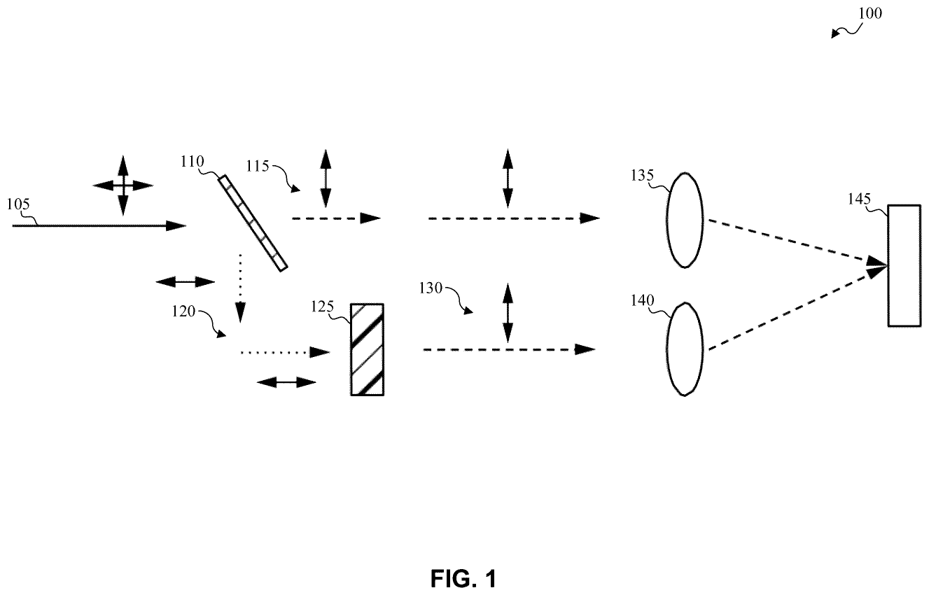

FIG. 1 illustrates an example system 100 in accordance with one or more implementations as described herein. In the illustrated example, system 100 may include polarization splitter 110 (e.g., curved optics and/or a metalens), polarization converter 125 (e.g., curved optics and/or a metalens), guiding optics 135, guiding optics 140 (e.g., lens, mirror, deflector, etc.), and beam receiving element 145. The guiding optics 135 and/or guiding optics 140 may include curved optics and/or one or more metalenses (e.g., metasurfaces, nanostructure surfaces, etc.).

As shown, incident light 105 may fall upon polarization splitter 110. It is noted that reference to beams of light and/or incident light (e.g., incident light 105) may refer to beams of any type of electromagnetic radiation or any form of electromagnetic radiation (e.g., heat, infrared, visible light, ultraviolet, x-rays, gamma rays, etc.). As shown, polarization splitter 110 may split incident light 105 into at least two beams of light. In the illustrated example, polarization splitter 110 may split incident light 105 into first beam of light 115 and second beam of light 120. In some cases, first beam of light 115 may have a first polarization state (e.g., vertical polarization) and second beam of light 120 may have a second polarization state (e.g., horizontal polarization) that is different from the first polarization state.

In the illustrated example, polarization converter 125 may convert second beam of light 120 to third beam of light 130. It is noted that third beam of light 130 may be referred to as polarization conversion of second beam of light 120. For example, polarization converter 125 may convert a polarization state of second beam of light 120 from the second polarization state to the first polarization state. For example, polarization converter 125 may convert second beam of light 120 from a cross/orthogonal linear light into a third opposite-handed polarization state that is a same-handed polarization state as first beam of light 120. Thus, third beam of light 130 may be second beam of light 120 in the first polarization state.

Although the illustrated example is based on a linear light source and/or linear polarization, the polarization of incident light 105 may be circular or elliptical. Accordingly, first beam of light 115 may include a first circular polarization, second beam of light 120 may include a second circular polarization different from the first circular polarization, and polarization converter 125 may convert the polarization state of second beam of light 120 from the second circular polarization to the first circular polarization.

In the illustrated example, guiding optics 135 may steer first beam of light 115 towards beam receiving element 145. Similarly, guiding optics 140 may steer third beam of light 130 towards beam receiving element 145. In some cases, beam receiving element 145 may be configured to receive a combination of first beam of light 115 and third beam of light 130. In some cases, beam receiving element 145 may combine first beam of light 115 and third beam of light 130 into a collinear beam. In some cases, guiding optics 135, guiding optics 140, and/or beam receiving element 145 may include at least one of a photodetector, a curved lens, a metalens, a nanostructure, or a mirror.

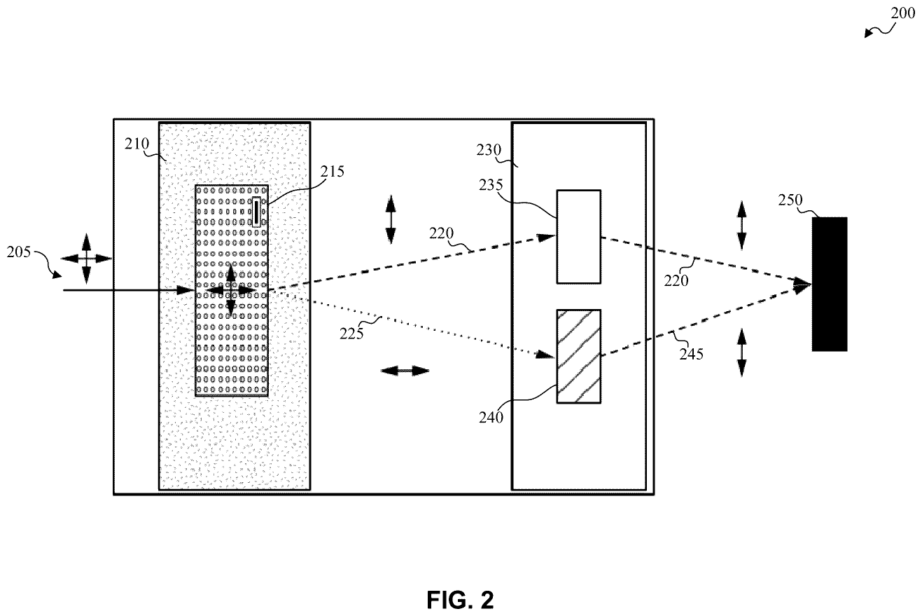

FIG. 2 illustrates an example system 200 in accordance with one or more implementations as described herein. In the illustrated example, system 200 may include substrate 210, beamsplitter metalens 215 (e.g., embedded in substrate 210), substrate 230, metalens 235, metalens 240, and beam receiving element 250. In some cases, metalens 235 and/or metalens 240 may be embedded in a shared substrate (e.g., substrate 230). In some cases, metalens 235 may be embedded in a first substrate and metalens 240 may be embedded in a second substrate different or separate from the first substrate. In some cases, metalens 215, metalens 235, and/or metalens 240 may be formed on the same substrate (e.g., substrate 210). Although system 200 is depicted in relation to linear polarization states, the systems and methods are applicable to various polarization states, including linear polarization, circular polarization, elliptical polarization, etc.

In the illustrated example, incident light 205 may fall upon system 200. As shown, incident light 205 may fall upon beamsplitter metalens 215. In some cases, beamsplitter metalens 215 may include one or more nanostructure elements. In some examples, metalens 235 may include one or more nanostructure elements and/or metalens 240 may include one or more nanostructure elements. As shown, incident light 205 may be unpolarized light.

In the illustrated example, incident light 205 may pass through beamsplitter metalens 215. As shown, beamsplitter metalens 215 may split incident light 205 into two beams of light (e.g., beam of light 220 and beam of light 225). In some cases, nanostructures of metalens 215 may be configured to split incident light 205 into two beams of light that are deflected based on the nanostructure elements. For example, beamsplitter metalens 215 may be configured to deflect or steer beam of light 220 towards metalens 235 and deflect or steer beam of light 225 towards metalens 240. As shown, beam of light 220 may have a first polarization state (e.g., a vertical polarization state in the provided example) and beam of light 225 may have a second polarization state (e.g., horizontal polarization state in the provided example) that is different from (e.g., perpendicular to) the first polarization state. Based on the nanostructure elements of beamsplitter metalens 215, beamsplitter metalens 215 may deflect light of the first polarization state towards metalens 235 and light of the second polarization state towards metalens 240.

In the illustrated example, metalens 235 may receive first beam of light 220 and deflect first beam of light 220 towards beam receiving element 250. In some cases, nanostructures of metalens 235 may be configured to deflect first beam of light 220 towards beam receiving element 250. For example, metalens 235 may allow first beam of light 220 to pass through metalens 235 without changing or converting a polarization state of first beam of light 220, and deflect or steer first beam of light 220 towards beam receiving element 250. As shown, first beam of light 220 enters metalens 235 in the first polarization state (e.g., vertical polarization in the provided example) and exits metalens 235 still in the first polarization state.

In the illustrated example, metalens 240 may receive second beam of light 225, converting second beam of light 225 into third beam of light 245 and deflecting third beam of light 245 towards beam receiving element 250. In some cases, nanostructures of metalens 240 may be configured to convert a polarization of second beam of light 225 and deflect the converted second beam of light 225 (e.g., third beam of light 245) towards beam receiving element 250.

In some cases, third beam of light 245 may be referred to as a deflected and converted version of second beam of light 225. For example, third beam of light 245 may be a version of second beam of light 225 (e.g., a converted polarization state version of second beam of light 225) after second beam of light 225 passes through metalens 240. Thus, metalens 240 (e.g., based on nanostructures of metalens 240) may allow second beam of light 225 to pass through metalens 240 while changing or converting a polarization state of second beam of light 225 and deflecting or steering the converted second beam of light 225 towards beam receiving element 250, where the deflection and the converted polarization state of second beam of light 225 is referred to as third beam of light 245 in the illustrated example. Thus, as shown, second beam of light 225 is incident on metalens 240 in the second polarization state (e.g., horizontal polarization in the provided example) and exits metalens 240 converted into the first polarization state (e.g., vertical polarization in the provided example), matching the polarization state of first beam of light 220.

In some examples, beam receiving element 145 may combine first beam of light 220 and third beam of light 245 into a collinear beam. In some cases, the collinear beam may be encoded with data and the encoded collinear beam may be communicated (e.g., wirelessly, by wire, by fiber optics, etc.) in a communication system. In some cases, the collinear beam may be used to improve one or polarization-based systems (e.g., increase signal strength, increase signal to noise ratio, etc.). For example, beam receiving element 145 may provide the collinear beam and/or use the collinear beam for one or more implementations of a polarization system that may include at least one of wireless communication systems, optical fibers, satellite communication system, antennas (e.g., enhance antenna gain), electromagnetic sensing systems, light sensing systems, remote sensing systems, image sensing systems, autonomous vehicle sensing systems, radar cross section (RCS) reduction systems, stereoisomer identification systems, electromagnetic shielding systems, and the like. In some cases, the collinear beam may help overcome polarization mismatch and multi-path fading in microwave and millimeter-wave communication channels. Additionally, or alternatively, beam receiving element 145 may provide the combined/collinear beam to a camera to enhance image clarity and/or improve the contrast and saturation of colors; to a microscope and/or spectrometer to enhance contrast and details; to a display to improve contrast and readability, reduce reflections from ambient light, and/or enhancing visibility in bright environments; to astronomy instruments such as telescopes to enhance image clarity and/or improve the contrast and saturation of colors; to communication systems to improve system performance; to a sensor in an internet of things (IoT) device to improve sensor performance; and/or to remote sensors for environmental monitoring.

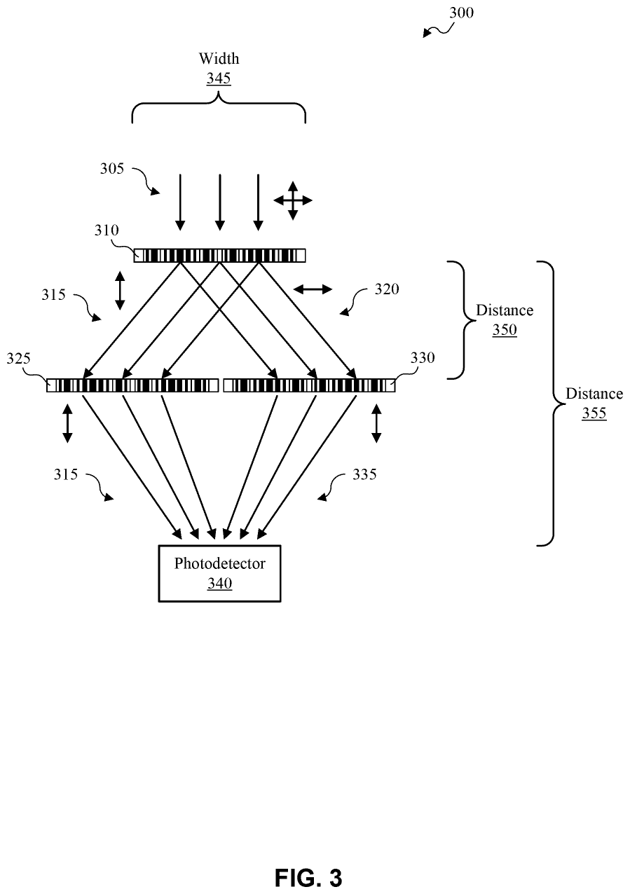

FIG. 3 illustrates an example system 300 in accordance with one or more implementations as described herein. In the illustrated example, system 300 may include beamsplitter metalens 310, metalens 325, metalens 330, and a beam receiving element (e.g., photodetector 340). In some cases, beamsplitter metalens 310, metalens 325, and/or metalens 330 may include one or more nanostructure elements, respectively. In some examples, the one or more nanostructure elements of a given metalens (e.g., beamsplitter metalens 310, metalens 325, and/or metalens 330) may include multilayer nanostructure elements (e.g., a metalens with one or more layers of nanostructure elements). In some cases, beamsplitter metalens 310 may be an example of beamsplitter metalens 215; metalens 325 may be an example of metalens 235; metalens 330 may be an example of metalens 240; and/or photodetector 340 may be an example of beam receiving element 250. Although system 300 is depicted in relation to linear polarization states, the systems and methods are applicable to various polarization states, including linear polarization, circular polarization, elliptical polarization, etc.

In the illustrated example, unpolarized light 305 is incident upon beamsplitter metalens 310. As shown, beamsplitter metalens 310 may split unpolarized light 305 into two or more beams of light (e.g., first beam of light 315 and second beam of light 320). As shown, beamsplitter metalens 310 may deflect light of unpolarized light 305 that is in a first polarization state towards metalens 325 and deflect light of unpolarized light 305 that is in a second polarization state towards metalens 330.

In some cases, metalens 325 may be configured as a defracting metalens (e.g., based on nanostructure elements of metalens 325). As shown, metalens 325 may receive first beam of light 315 in a first polarization state (e.g., vertical polarization state) and may deflect first beam of light 315 in the first polarization state towards photodetector 340.

In some cases, metalens 330 may be configured as a defracting metalens and a converting metalens (e.g., based on nanostructure elements of metalens 330). For example, metalens 330 may be configured to convert a polarization state of light incident upon metalens 330. As shown, metalens 330 may receive second beam of light 320 in a second polarization state (e.g., horizontal polarization state), convert second beam of light 320 from the second polarization state to the first polarization state (e.g., vertical polarization state), and deflect the converted second beam of light 320 towards photodetector 340. In the illustrated example, second beam of light 320 converted to the first polarization state and deflected towards photodetector 340 is depicted as third beam of light 335.

Although system 300 is depicted as maintaining a vertical polarization state and converting a horizontal polarization state to a vertical polarization state, some embodiments of system 300 may include maintaining a horizontal polarization state and converting a vertical polarization state to a horizontal polarization state. For example, the first polarization state may be a horizonal polarization state and the second polarization state may be a vertical polarization state converted to a horizontal polarization state. Alternatively, the first polarization state may be a clockwise polarization state and the second polarization state may be a counter-clockwise polarization state converted to a clockwise polarization state. Alternatively, the first polarization state may be a counter-clockwise polarization state and the second polarization state may be a clockwise polarization state converted to a counter-clockwise polarization.

In some examples, the systems and methods described herein may be based on one or more dimensions of a given system. As shown, beamsplitter metalens 310 may be configured with width 345. In the illustrated example, a width of metalens 325 may be less, more, or the same as width 345. In some cases, a width of metalens 330 may be less, more, or the same as width 345. As shown, metalens 325 and/or metalens 330 may be positioned distance 350 from beamsplitter metalens 310. In some cases, photodetector 340 may be positioned distance 355 from beamsplitter metalens 310. In some examples, distance 350 may be within a range of one time to two times width 345 (e.g., 1.0 times width 345, 1.2 times width 345, 1.3 times width 345, 1.8 times width 345, 2.0 times width 345, etc.). In some examples, distance 355 may be within a range of one time to four times a width of the beamsplitter metalens (e.g., 1.0 times width 345, 1.5 times width 345, 2.5 times width 345, 3.5 times width 345, 4.0 times width 345, etc.).

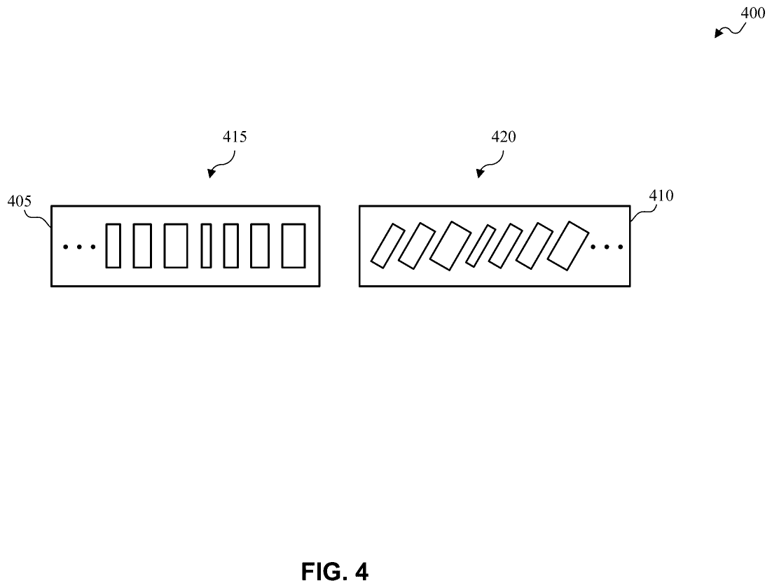

FIG. 4 illustrates an example metalens system 400 in accordance with one or more implementations as described herein. In the illustrated example, metalens system 400 may include metalens 405 and metalens 410.

In the illustrated example, metalens 405 may depict a segment of a defracting metalens, while metalens 410 may depict a segment of a converting defracting metalens. Examples of a defracting metalens may include at least one of metalens 235, metalens 325, or metalens 405. Examples of a converting defracting metalens may include at least one of polarization converter 125, metalens 240, metalens 330, metalens 410.

In the illustrated example, metalens 405 may include one or more nanostructure elements (e.g., nanostructure elements 415) and/or metalens 410 may include one or more nanostructure elements (e.g., nanostructure elements 420). As shown, at least one nanostructure element of metalens 405 may be configured with a first orientation (e.g., a vertical orientation relative to the orientation of FIG. 4). As shown, at least one nanostructure element of metalens 410 may be configured with a second orientation (e.g., a tilted orientation relative to the first orientation). In some cases, the first orientation may be parallel or relatively parallel to light incident to metalens system 400 (e.g., parallel or relatively parallel to incident light 305), while the second orientation may be tilted relative to the incident light.

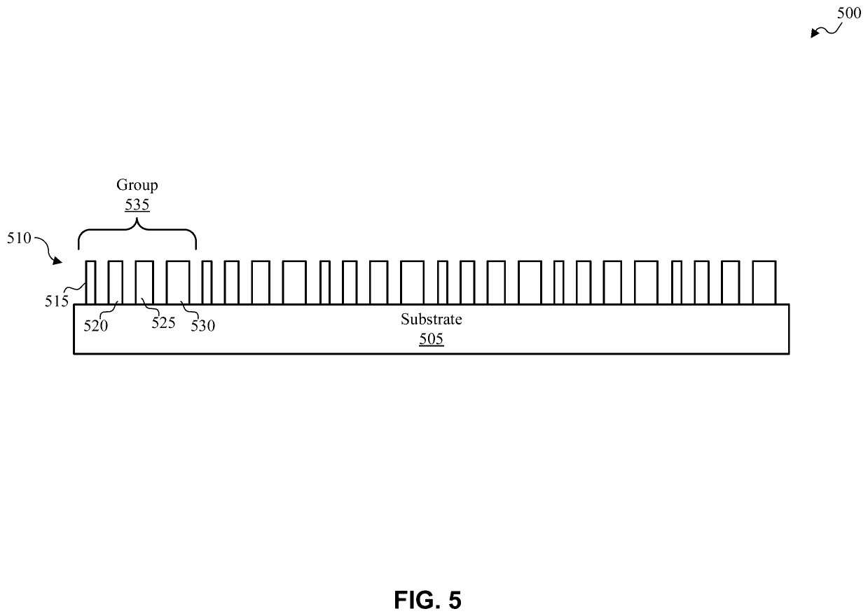

FIG. 5 illustrates an example metalens 500 in accordance with one or more implementations as described herein. In the illustrated example, metalens 500 may include substrate 505 and one or more nanostructure elements (e.g., nanostructure elements 510). As shown, nanostructure elements 5150 may include element 515, element 520, element 525, and element 530. In some cases, metalens 500 may be an example of a beamsplitter metalens (e.g., beamsplitter metalens 215, beamsplitter metalens 310), a defracting metalens (e.g., metalens 235, metalens 325, metalens 405), and/or a converting defracting metalens (e.g., polarization converter 125, metalens 240, metalens 330, metalens 410).

In some examples, metalens 500 may include repeating groups of nanostructure elements (e.g., group 535, repetitions of group 535). As shown, group 535 may include at least element 515 and element 520. In some cases, the nanostructure elements of group 535 may be repeated one or more times across metalens 500. In some cases, a width of group 535 may be within a range of one-fourth to three times a wavelength of incident light (e.g., 0.25 times 2, 1 times 2, 2 times 2, 3 times A, where A represents the wavelength of incident light such as incident light 305).

In some cases, a dimension of element 515 and/or element 520 (e.g., height, width, diameter, shape) may be configured to induce varying phase shifts based on the polarization state of light incident on the respective nanostructure elements.

In some examples, element 515 may induce a first phase shift on light of a first polarization state (e.g., beam of light 220, first beam of light 315) and element 515 may induce a second phase shift on light of a second polarization state (e.g., beam of light 225, second beam of light 320), where the first phase shift is different from the second phase shift.

In some examples, element 520 may induce a third phase shift on light of the first polarization state (e.g., beam of light 220, first beam of light 315) and element 520 may induce a fourth phase shift on light of the second polarization state (e.g., beam of light 225, second beam of light 320), where the third phase shift is different from the fourth phase shift. In some cases, the first phase shift is different from the second phase shift, the third phase shift, and the fourth phase shift. In some cases, the second phase shift is different from the third phase shift and the fourth phase shift.

In some examples, a first element of group 535 (e.g., element 515) may be configured to induce a phase shift of 0 radians on light of a first polarization state (e.g., vertical polarization); a second element of group 535 (e.g., element 520) may be configured to induce a phase shift of pi/2 radians on light of the first polarization state; a third element of group 535 (e.g., element 525) may be configured to induce a phase shift of pi radians on light of the first polarization state; a fourth element of group 535 (e.g., element 530) may be configured to induce a phase shift of 3 pi/2radians on light of the first polarization state.

In some examples, the first element of group 535 (e.g., element 515) may be configured to induce a phase shift of 3 pi/2 radians on light of a second polarization state (e.g., horizontal polarization); the second element of group 535 (e.g., element 520) may be configured to induce a phase shift of pi radians on light of the second polarization state; the third element of group 535 (e.g., element 525) may be configured to induce a phase shift of pi/2 radians on light of the second polarization state; the fourth element of group 535 (e.g., element 530) may be configured to induce a phase shift of 0 radians on light of the second polarization state.

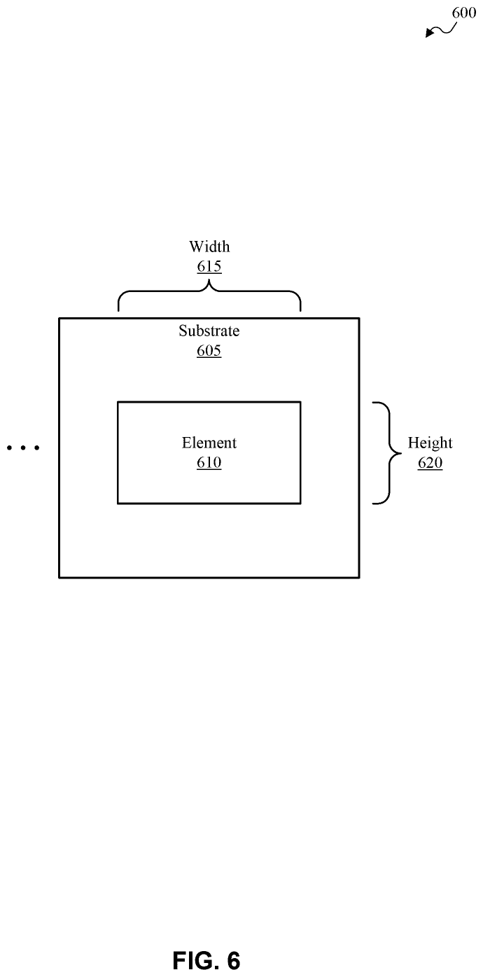

FIG. 6 illustrates an example of metalens 600 in accordance with one or more implementations as described herein. In the illustrated example, metalens 600 may depicts a portion of a metalens of the systems and methods described herein. As shown, metalens 600 may include substrate 605 and element 610. In some cases, nanostructure elements (e.g., element 610) may be embedded in a substrate (e.g., substrate 605). Additionally, or alternatively, nanostructure elements (e.g., nanostructure elements 510) may be formed on a surface of a substrate (e.g., substrate 505). In some cases, at least a portion of substrate 505 may include and/or be formed with silicon dioxide. In some cases, at least a portion of element 510 may include and/or be formed silicon.

In the illustrated example, one or more dimensions of element 610 may be based on experimentation. For example, element 610 may be exposed to one or more forms of electromagnetics radiation (e.g., visible light, infrared, x-rays, etc.). Additionally, or alternatively, element 610 may be exposed to light of one or more polarization states (e.g., light of a first polarization state, light of a second polarization state, etc.). Additionally, or alternatively, element 610 may be exposed to light of one or more wavelengths (e.g., light of a first wavelength, light of a second wavelength different from the first wavelength, etc.).

In some examples, one or more dimensions of element 610 may be determined based on observations of element 610 being exposed to the various forms and/or variations of electromagnetic radiation. For example, width 615 and/or height 620 of element 610 may be determined based on the properties (e.g., defraction properties, polarization conversion properties, phase shift properties) observed in relation to element 610 being exposed to the various forms and/or variations of electromagnetic radiation.

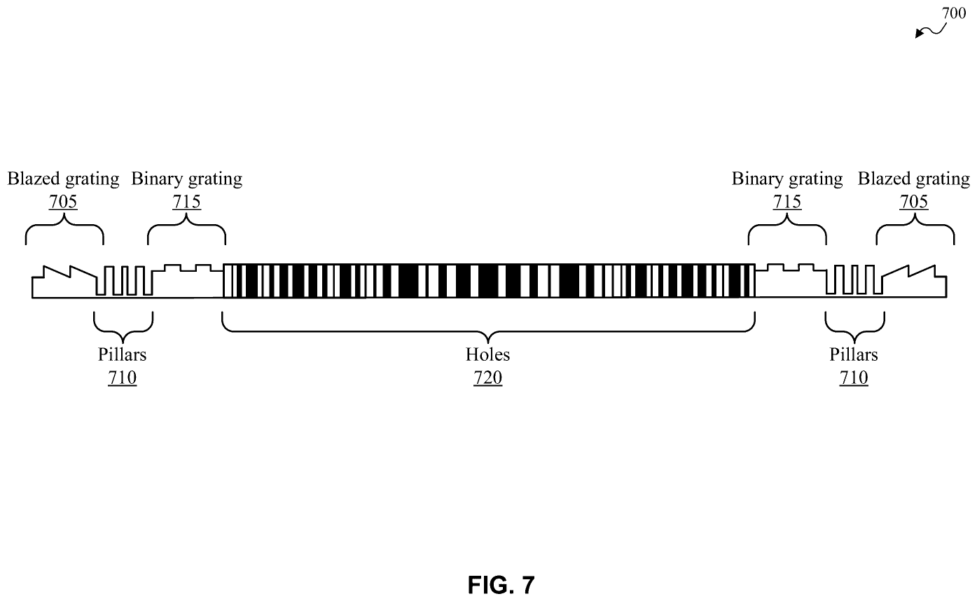

FIG. 7 illustrates an example of a metalens 700 in accordance with one or more implementations as described herein. In some examples, metalens 700 depicts a side view of a metalens that may be part of a thermal imaging system, such as thermal imaging system 100 of FIG. 1 and/or thermal imaging system 200 of FIG. 2. Metalens 700 may be an example of a beamsplitter metalens (e.g., beamsplitter metalens 215, beamsplitter metalens 310), a defracting metalens (e.g., metalens 235, metalens 325, metalens 405), a converting defracting metalens (e.g., polarization converter 125, metalens 240, metalens 330, metalens 410), and/or metalens 500.

Metalens 700 may include at least one nanostructure. In some cases, a top surface of metalens 700 may include one or more nanostructures. Additionally, or alternatively, a bottom surface of metalens 700 may include one or more nanostructures. In some examples, at least one nanostructure of metalens 700 may be formed based on dry etching and/or wet etching.

In the illustrated example, metalens 700 may include nanostructures such as blazed gratings 705, pillars 710, binary gratings 715, and holes 720. In some examples, metalens 700 may include one or more patterns of diffraction grating (e.g., a pattern of blazed grating 705 and/or binary grating 715). In some cases, pillars 710 may include one or more patterns of pillars. In some implementations, holes 720 may include one or more patterns of holes (e.g., of a silicon hole-based metalens).

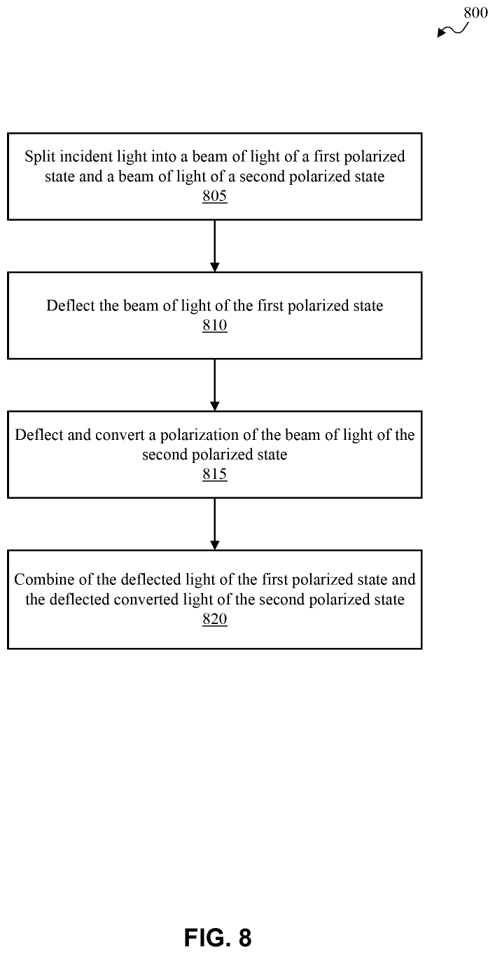

FIG. 8 depicts a flow diagram illustrating an example method 800 associated with the disclosed systems, in accordance with example implementations described herein. In some configurations, method 800 may be implemented by at least one system and/or at least one component of at least one system described herein. The depicted method 800 is just one implementation and one or more operations of method 800 may be rearranged, reordered, omitted, and/or otherwise modified such that other implementations are possible and contemplated.

At 805, method 800 may include splitting incident light into a beam of light of a first polarized state and a beam of light of a second polarized state. For example, method 800 may include splitting, via a beamsplitter metalens, incident light that is unpolarized into a beam of light of a first polarized state and a beam of light of a second polarized state.

At 810, method 800 may include deflecting the beam of light of the first polarized state. For example, method 800 may include deflecting, via a first metalens, the beam of light of the first polarized state received from the beamsplitter metalens.

At 815, method 800 may include deflecting and convert a polarization of the beam of light of the second polarized state. For example, method 800 may include deflecting, via a second metalens adjacent to the first metalens, the beam of light of the second polarized state received from the beamsplitter metalens. In some cases, method 800 may include converting, via the second metalens, a polarization of the beam of light of the second polarized state in conjunction with the deflecting via the second metalens.

At 820, method 800 may include combining the deflected light of the first polarized state and the deflected converted light of the second polarized state. For example, method 800 may include combining the deflected light of the first polarized state and the deflected converted light of the second polarized state into a collinear beam. In some cases, guiding optics may be used to combine the deflected light of the first polarized state and the deflected converted light of the second polarized state into a collinear beam. In some cases, method 800 may include receiving, via a beam receiving element, a combination of the deflected light of the first polarized state from the first metalens and the deflected converted light of the second polarized state from the second metalens. In some cases, the beam receiving element may include at least one of a photodetector, a curved lens, a metalens, a nanostructure, or a mirror.

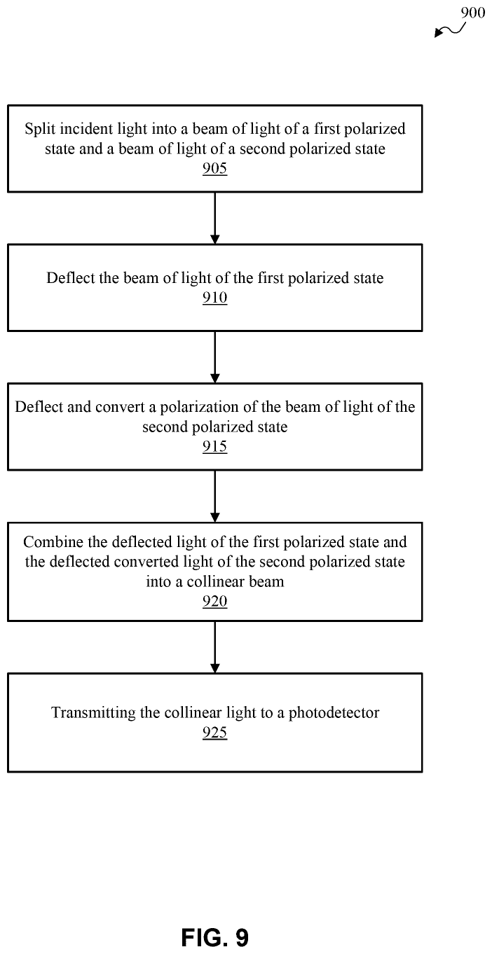

FIG. 9 depicts a flow diagram illustrating an example method 900 associated with the disclosed systems, in accordance with example implementations described herein. In some configurations, method 900 may be implemented by at least one system and/or at least one component of at least one system described herein. The depicted method 900 is just one implementation and one or more operations of method 900 may be rearranged, reordered, omitted, and/or otherwise modified such that other implementations are possible and contemplated.

At 905, method 900 may include splitting incident light into a beam of light of a first polarized state and a beam of light of a second polarized state. For example, method 900 may include splitting, via a beamsplitter metalens, incident light that is unpolarized into a beam of light of a first polarized state and a beam of light of a second polarized state.

At 910, method 900 may include deflecting the beam of light of the first polarized state. For example, method 900 may include deflecting, via a first metalens, the beam of light of the first polarized state received from the beamsplitter metalens.

At 915, method 900 may include deflecting and convert a polarization of the beam of light of the second polarized state. For example, method 900 may include deflecting, via a second metalens adjacent to the first metalens, the beam of light of the second polarized state received from the beamsplitter metalens. In some cases, method 900 may include converting, via the second metalens, a polarization of the beam of light of the second polarized state in conjunction with the deflecting via the second metalens.

At 920, method 900 may include combining the deflected light of the first polarized state and the deflected converted light of the second polarized state. For example, method 900 may include combining the deflected light of the first polarized state and the deflected converted light of the second polarized state into a collinear beam. In some cases, guiding optics may be used to combine the deflected light of the first polarized state and the deflected converted light of the second polarized state into a collinear beam. In some cases, method 900 may include receiving, via a beam receiving element, a combination of the deflected light of the first polarized state from the first metalens and the deflected converted light of the second polarized state from the second metalens. In some cases, the beam receiving element may include at least one of a photodetector, a curved lens, a metalens, a nanostructure, or a mirror.

At 925, method 900 may include transmitting the collinear light to a photodetector. For example, one or more optical components (e.g., metalens, curved lens, nanostructure element, mirror, etc.) may direct the collinear light towards a photodetector and/or to another component in an optical system (e.g., another lens, mirror, pinhole, fiber coupler, photodetector, sensor, etc.). In some cases, the photodetector may be located in a device that includes the beamsplitter metalens, the first metalens, and the second metalens. Alternatively, the beamsplitter metalens, the first metalens, and the second metalens may be located in a first device and the photodetector may be located in a second device separate from the first device. For example, the collinear beam may be configured to communicate information between the first device and the second device.

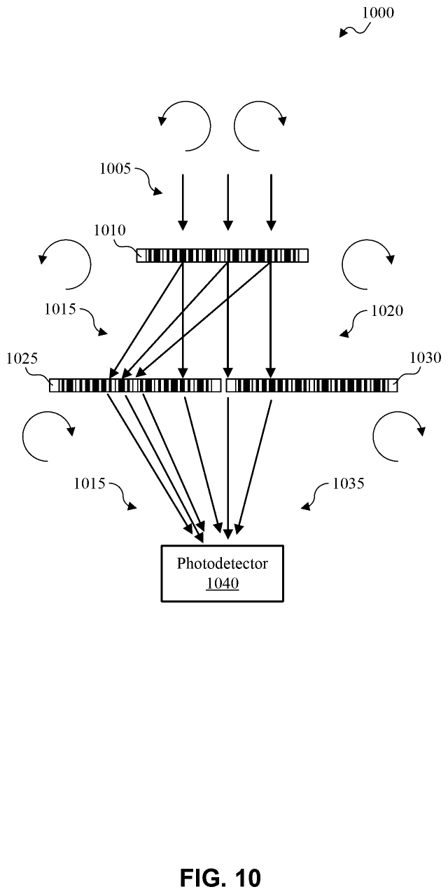

FIG. 10 illustrates an example system 1000 in accordance with one or more implementations as described herein. In the illustrated example, system 1000 may include beamsplitter metalens 1010, metalens 1025, metalens 1030, and a beam receiving element (e.g., photodetector 1040). In some cases, beamsplitter metalens 1010, metalens 1025, and/or metalens 1030 may include one or more nanostructure elements, respectively. In some examples, the one or more nanostructure elements of a given metalens (e.g., beamsplitter metalens 1010, metalens 1025, and/or metalens 1030) may include multilayer nanostructure elements (e.g., a metalens with one or more layers of nanostructure elements). In some implementations, metalens 1025 and metalens 1030 may be adjoined or incorporated as a single metalens to perform the operations described herein. In some cases, beamsplitter metalens 1010 may be an example of beamsplitter metalens 215; metalens 1025 may be an example of metalens 235; metalens 1030 may be an example of metalens 240; and/or photodetector 1040 may be an example of beam receiving element 250. Although system 1000 is depicted in relation to circular polarization states, the systems and methods are applicable to various polarization states, including linear polarization, circular polarization, elliptical polarization, etc.

In the illustrated example, unpolarized light 1005 is incident upon beamsplitter metalens 1010. As shown, beamsplitter metalens 1010 may split unpolarized light 1005 into two or more beams of light (e.g., first beam of light 1015 and second beam of light 1020). As shown, beamsplitter metalens 1010 may deflect light of unpolarized light 1005 that is in a first polarization state towards metalens 1025 and deflect light of unpolarized light 1005 that is in a second polarization state towards metalens 1030.

In some cases, metalens 1025 may be configured as a defracting metalens (e.g., based on nanostructure elements of metalens 1025). As shown, metalens 1025 may receive first beam of light 1015 in a first polarization state (e.g., counter-clockwise polarization state) and may deflect first beam of light 1015 in the first polarization state towards photodetector 1040.

In some cases, metalens 1030 may be configured as a defracting metalens and a converting metalens (e.g., based on nanostructure elements of metalens 1030). For example, metalens 1030 may be configured to convert a polarization state of light incident upon metalens 1030. As shown, metalens 1030 may receive second beam of light 1020 in a second polarization state (e.g., clockwise polarization state), convert second beam of light 1020 from the second polarization state to the first polarization state (e.g., counter-clockwise polarization state), and deflect the converted second beam of light 1020 towards photodetector 1040. In the illustrated example, second beam of light 1020 converted to the first polarization state and deflected towards photodetector 1040 is depicted as third beam of light 1035. Although system 1000 is depicted as maintaining a counter-clockwise polarization state and converting a clockwise polarization state to a counter-clockwise polarization state, some embodiments of system 1000 may include maintaining a clockwise polarization state and converting a counter-clockwise polarization state to a clockwise polarization state.

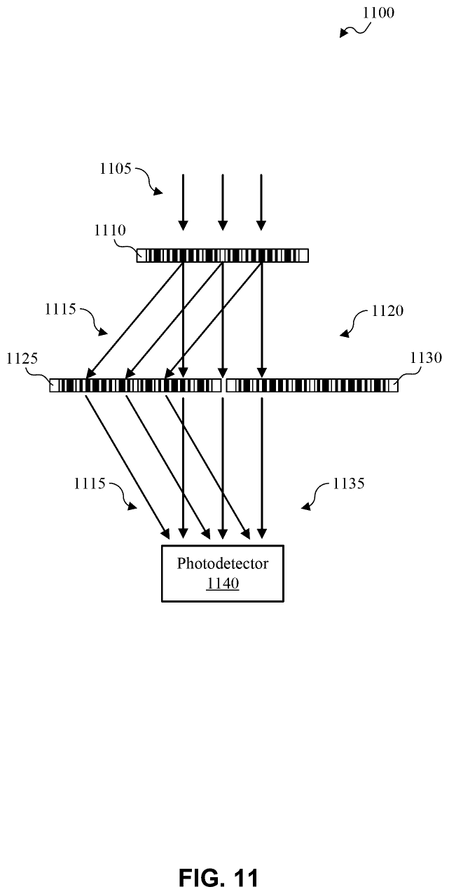

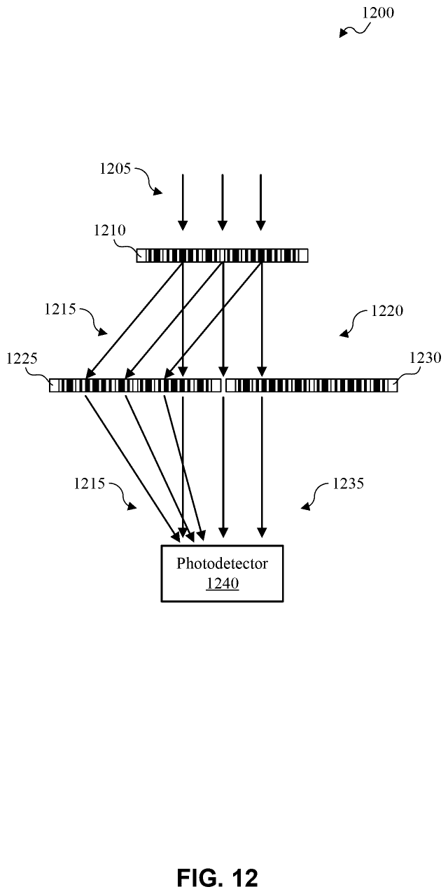

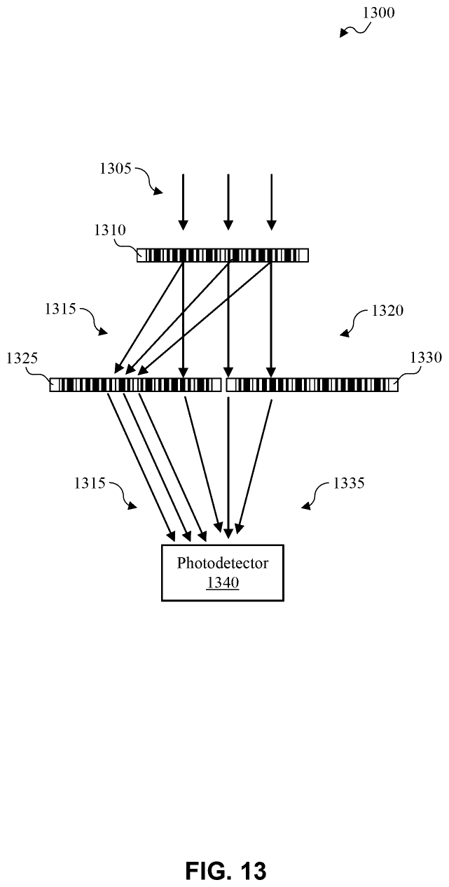

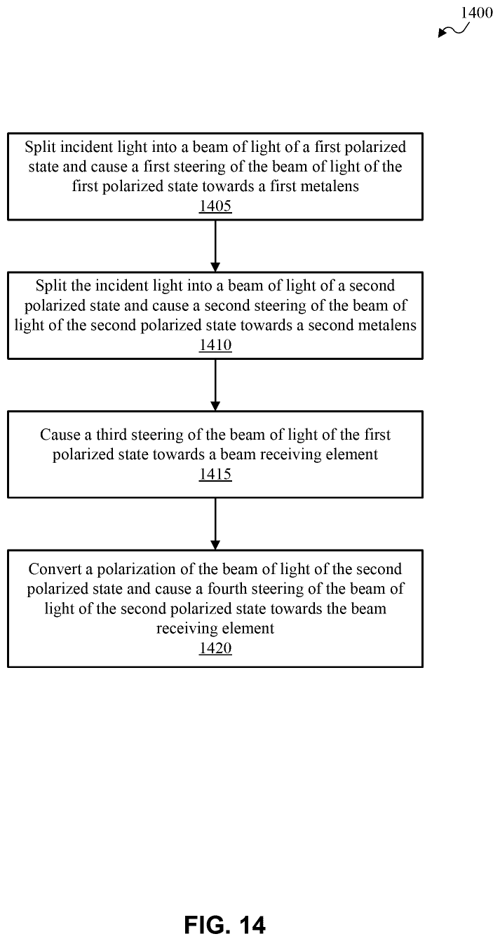

One or more aspects of system 1000 may be based on steering of a beam of light. Steering a beam of light (e.g., at least in the case of system 1000 of FIG. 10, system 1100 of FIG. 11, system 1200 of FIG. 12, system 1300 of FIG. 13, method 1400 of FIG. 14) may include focusing light towards a point or a region of an object or surface (e.g., of a metalens, of a beam receiving element, of a photodetector, etc.), bending light (e.g., bending light uniformly), passing light (e.g., passing light straight through a medium such as a metalens), or any combination thereof. In some cases, a steering of a beam of light may depend on the polarization state of the light and/or one or more aspects of the medium (e.g., configuration of nanostructure elements of a metalens) through which the beam of light is passing.

In some cases, a beamsplitter metalens may split incident light into a first polarized state and a second polarized state and cause a first steering on the first polarized state and cause a second steering on the second polarized state. In some cases, the beamsplitter may be configured to cause a first steering on a first polarization of light incident on the beamsplitter and cause a second steering on a second polarization of light incident on the beamsplitter. In some cases, the steering of the first polarized state may match the steering of the second polarized state (e.g., both focused, both bent, both passed through, etc.). Alternatively, the first steering may differ from the second steering (e.g., focus first beam and bend second beam; focus first beam and pass second beam; pass first beam and pass second beam; or any other possible combination of steering). Focusing a beam of light may include steering the beam of light towards a point or region of a beam receiving element. Bending a beam of light may include bending bending light uniformly (e.g., in a collinear beam for example). Passing a beam of light may include allowing the beam of light to pass straight through the medium.

As shown, beamsplitter metalens 1010 may focus first beam of light 1015 towards a point or region of metalens 1025 (e.g., a first steering of first beam of light 1015), and pass second beam of light 1020 straight through to metalens 1025 and/or metalens 1030 (e.g., a second steering of second beam of light 1020).

In some cases, a first metalens may cause a third steering on the first polarized state. A second metalens may convert a polarization state of the second polarized state and cause a fourth steering on the second polarized state. In some cases, the steering of the third polarized state may match the steering of the fourth polarized state (e.g., both focused, both bent, both passed through, etc.). Alternatively, the third steering may differ from the fourth steering (e.g., first metalens focuses first beam and second metalens bends second beam; first metalens focuses first beam and second metalens passes second beam; first metalens passes first beam and second metalens bends second beam; or any other possible combination of steering).

As shown, first metalens 1025 may focus first beam of light 1015 towards a point or region of photodetector 1040 (e.g., a third steering of first beam of light 1015), and second metalens 1030 may focus second beam of light 1020 towards a point or region of photodetector 1040 (e.g., a fourth steering of second beam of light 1020).

FIG. 11 illustrates an example system 1100 in accordance with one or more implementations as described herein. In the illustrated example, system 1100 may include beamsplitter metalens 1110, metalens 1125, metalens 1130, and a beam receiving element (e.g., photodetector 1140). In some cases, beamsplitter metalens 1110, metalens 1125, and/or metalens 1130 may include one or more nanostructure elements, respectively. In some examples, the one or more nanostructure elements of a given metalens (e.g., beamsplitter metalens 1110, metalens 1125, and/or metalens 1130) may include multilayer nanostructure elements (e.g., a metalens with one or more layers of nanostructure elements). In some implementations, metalens 1125 and metalens 1130 may be adjoined or incorporated as a single metalens to perform the operations described herein. In some cases, beamsplitter metalens 1110 may be an example of beamsplitter metalens 215; metalens 1125 may be an example of metalens 235; metalens 1130 may be an example of metalens 240; and/or photodetector 1140 may be an example of beam receiving element 250.

In the illustrated example, unpolarized light 1105 is incident upon beamsplitter metalens 1110. As shown, beamsplitter metalens 1110 may split unpolarized light 1105 into two or more beams of light (e.g., first beam of light 1115 and second beam of light 1120). As shown, beamsplitter metalens 1110 may deflect light of unpolarized light 1105 that is in a first polarization state towards metalens 1125 and deflect light of unpolarized light 1105 that is in a second polarization state towards metalens 1130.

As shown, metalens 1125 may receive first beam of light 1115 in a first polarization state and may deflect first beam of light 1115 in the first polarization state towards photodetector 1140. As shown, metalens 1130 may receive second beam of light 1120 in a second polarization state, convert second beam of light 1120 from the second polarization state to the first polarization state. In the illustrated example, second beam of light 1120 converted to the first polarization state and deflected towards photodetector 1140 is depicted as third beam of light 1135.

As shown, beamsplitter metalens 1110 may bend first beam of light 1115 towards metalens 1125 (e.g., a first steering of first beam of light 1115), and pass second beam of light 1120 straight through to metalens 1125 and/or metalens 1130 (e.g., a second steering of second beam of light 1120).

As shown, first metalens 1125 may bend first beam of light 1115 towards photodetector 1140 (e.g., a third steering of first beam of light 1115), and second metalens 1130 may pass second beam of light 1120 straight through towards photodetector 1140 (e.g., a fourth steering of second beam of light 1120).

FIG. 12 illustrates an example system 1200 in accordance with one or more implementations as described herein. In the illustrated example, system 1200 may include beamsplitter metalens 1210, metalens 1225, metalens 1230, and a beam receiving element (e.g., photodetector 1240). In some cases, beamsplitter metalens 1210, metalens 1225, and/or metalens 1230 may include one or more nanostructure elements, respectively. In some examples, the one or more nanostructure elements of a given metalens (e.g., beamsplitter metalens 1210, metalens 1225, and/or metalens 1230) may include multilayer nanostructure elements (e.g., a metalens with one or more layers of nanostructure elements). In some implementations, metalens 1225 and metalens 1230 may be adjoined or incorporated as a single metalens to perform the operations described herein. In some cases, beamsplitter metalens 1210 may be an example of beamsplitter metalens 215; metalens 1225 may be an example of metalens 235; metalens 1230 may be an example of metalens 240; and/or photodetector 1240 may be an example of beam receiving element 250.

In the illustrated example, unpolarized light 1205 is incident upon beamsplitter metalens 1210. As shown, beamsplitter metalens 1210 may split unpolarized light 1205 into two or more beams of light (e.g., first beam of light 1215 and second beam of light 1220). As shown, beamsplitter metalens 1210 may deflect light of unpolarized light 1205 that is in a first polarization state towards metalens 1225 and deflect light of unpolarized light 1205 that is in a second polarization state towards metalens 1230.

As shown, metalens 1225 may receive first beam of light 1215 in a first polarization state and may deflect first beam of light 1215 in the first polarization state towards photodetector 1240. As shown, metalens 1230 may receive second beam of light 1220 in a second polarization state, convert second beam of light 1220 from the second polarization state to the first polarization state. In the illustrated example, second beam of light 1220 converted to the first polarization state and deflected towards photodetector 1240 is depicted as third beam of light 1235.

As shown, beamsplitter metalens 1210 may bend first beam of light 1215 towards metalens 1225 (e.g., a first steering of first beam of light 1215), and pass second beam of light 1220 straight through to metalens 1225 and/or metalens 1230 (e.g., a second steering of second beam of light 1220).

As shown, first metalens 1225 may focus first beam of light 1215 towards a point or region of photodetector 1240 (e.g., a third steering of first beam of light 1215), and second metalens 1230 may pass second beam of light 1220 straight through towards photodetector 1240 (e.g., a fourth steering of second beam of light 1220).

FIG. 13 illustrates an example system 1300 in accordance with one or more implementations as described herein. In the illustrated example, system 1300 may include beamsplitter metalens 1310, metalens 1325, metalens 1330, and a beam receiving element (e.g., photodetector 1340). In some cases, beamsplitter metalens 1310, metalens 1325, and/or metalens 1330 may include one or more nanostructure elements, respectively. In some examples, the one or more nanostructure elements of a given metalens (e.g., beamsplitter metalens 1310, metalens 1325, and/or metalens 1330) may include multilayer nanostructure elements (e.g., a metalens with one or more layers of nanostructure elements). In some implementations, metalens 1325 and metalens 1330 may be adjoined or incorporated as a single metalens to perform the operations described herein. In some cases, beamsplitter metalens 1310 may be an example of beamsplitter metalens 215; metalens 1325 may be an example of metalens 235; metalens 1330 may be an example of metalens 240; and/or photodetector 1340 may be an example of beam receiving element 250.

In the illustrated example, unpolarized light 1305 is incident upon beamsplitter metalens 1310. As shown, beamsplitter metalens 1310 may split unpolarized light 1305 into two or more beams of light (e.g., first beam of light 1315 and second beam of light 1320). As shown, beamsplitter metalens 1310 may deflect light of unpolarized light 1305 that is in a first polarization state towards metalens 1325 and deflect light of unpolarized light 1305 that is in a second polarization state towards metalens 1330.

As shown, metalens 1325 may receive first beam of light 1315 in a first polarization state and may deflect first beam of light 1315 in the first polarization state towards photodetector 1340. As shown, metalens 1330 may receive second beam of light 1320 in a second polarization state, convert second beam of light 1320 from the second polarization state to the first polarization state. In the illustrated example, second beam of light 1320 converted to the first polarization state and deflected towards photodetector 1340 is depicted as third beam of light 1335.

As shown, beamsplitter metalens 1310 may focus first beam of light 1315 towards a point or region of metalens 1325 (e.g., a first steering of first beam of light 1315), and pass second beam of light 1320 straight through to metalens 1325 and/or metalens 1330 (e.g., a second steering of second beam of light 1320).

As shown, first metalens 1325 may bend first beam of light 1315 towards photodetector 1140 (e.g., a third steering of first beam of light 1315), and second metalens 1330 may focus second beam of light 1320 towards a point or region of photodetector 1340 (e.g., a fourth steering of second beam of light 1320).

FIG. 14 depicts a flow diagram illustrating an example method 1400 associated with the disclosed systems, in accordance with example implementations described herein. In some configurations, method 1400 may be implemented by at least one system and/or at least one component of at least one system described herein. The depicted method 1400 is just one implementation and one or more operations of method 1400 may be rearranged, reordered, omitted, and/or otherwise modified such that other implementations are possible and contemplated.

At 1405, method 1400 may include splitting incident light into a beam of light of a first polarized state and causing a first steering of the beam of light of the first polarized state towards a first metalens. For example, method 1400 may include splitting, via a beamsplitter metalens, incident light into a beam of light of a first polarized state and causing a first steering of the beam of light of the first polarized state towards a first metalens.

At 1410, method 1400 may include splitting incident light into a beam of light of a second polarized state and causing a second steering of the beam of light of the second polarized state towards a second metalens. For example, method 1400 may include splitting, via a beamsplitter metalens, incident light into a beam of light of a second polarized state and causing a second steering of the beam of light of the second polarized state towards a second metalens.

At 1415, method 1400 may include causing a third steering of the beam of light of the first polarized state towards a beam receiving element. For example, method 1400 may include causing, via the first metalens adjacent to the second metalens, a third steering of the beam of light of the first polarized state towards the beam receiving element.

At 1420, method 1400 may include converting a polarization of the beam of light of the second polarized state and causing a fourth steering of the beam of light of the second polarized state towards the beam receiving element. For example, method 1400 may include converting, via the second metalens, a polarization of the beam of light of the second polarized state and causing, via the second metalens, a fourth steering of the beam of light of the second polarized state towards the beam receiving element. In some cases, converting a polarization of the beam of light of the second polarized state may include converting the polarization state from vertical to horizontal, from horizontal to vertical, from clockwise to counterclockwise, from counter clockwise to clockwise, etc.

In some cases, guiding optics may be used to combine the steered light of the first polarized state and the steered converted light of the second polarized state. In some cases, method 1400 may include receiving, via a beam receiving element, a combination of the steered light of the first polarized state from the first metalens and the steered converted light of the second polarized state from the second metalens. In some cases, the beam receiving element may include at least one of a photodetector, a curved lens, a metalens, a nanostructure, and/or a mirror.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wired and/or wireless communication device such as a switch, router, network interface controller, cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be wireless, wired, mobile, and/or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™M, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example an FPGA (field programmable gate array) or an ASIC (application-specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A polarization filter comprising:
a beamsplitter metalens to split incident light that is unpolarized into a beam of light of a first polarized state and a beam of light of a second polarized state;
a first metalens to deflect the beam of light of the first polarized state received from the beamsplitter metalens;
a second metalens adjacent to the first metalens, the second metalens to deflect the beam of light of the second polarized state received from the beamsplitter metalens and to convert a polarization of the beam of light of the second polarized state; and
a beam receiving element to receive a combination of the deflected light of the first polarized state from the first metalens and the deflected converted light of the second polarized state from the second metalens, the beam receiving element comprising at least one of a photodetector, a curved lens, a metalens, a nanostructure, or a mirror.

2. The polarization filter of claim 1, wherein the second metalens is configured to convert the beam of light of the second polarized state from the second polarized state to the first polarized state.

3. The polarization filter of claim 1, wherein at least one nanostructure element of the beamsplitter metalens induces a phase shift within a range of 0 degrees to 270 degrees.

4. The polarization filter of claim 1, wherein:
a first element of the beamsplitter metalens induces a first phase shift on a portion of the incident light that is in the first polarized state, and
the first element of the beamsplitter metalens induces a second phase shift different from the first phase shift on a portion of the incident light that is in the second polarized state.

5. The polarization filter of claim 4, wherein:
a second element of the beamsplitter metalens induces a third phase shift on the portion of the incident light that is in the first polarized state,
the second element of the beamsplitter metalens induces a fourth phase shift different from the third phase shift on the portion of the incident light that is in the second polarized state,
the first phase shift is different from the third phase shift and the fourth phase shift, and
the second phase shift is different from the third phase shift and the fourth phase shift.

6. The polarization filter of claim 1, wherein at least one of the beamsplitter metalens, the first metalens, or the second metalens comprise repeating groups of nanostructure elements.

7. The polarization filter of claim 6, wherein a width of a group of nanostructure elements of the repeating groups of nanostructure elements is within a range of one-fourth to three times a wavelength of the incident light.

8. The polarization filter of claim 1, wherein a distance from the beamsplitter metalens to at least one of the first metalens or the second metalens is within a range of one times to two times a width of the beamsplitter metalens.

9. The polarization filter of claim 1, wherein a distance from the beamsplitter metalens to the beam receiving element is within a range of one time to four times a width of the beamsplitter metalens.

10. The polarization filter of claim 1, wherein:
a nanostructure element of the first metalens corresponds to a nanostructure element of the second metalens, and
an orientation of the nanostructure element of the second metalens is tilted with respect to an orientation of the nanostructure element of the first metalens.

11. The polarization filter of claim 1, wherein at least one of the beamsplitter metalens, the first metalens, or the second metalens comprise at least one of silicon dioxide, silicon nitride, or a complementary metal-oxide-semiconductor.

12. The polarization filter of claim 1, wherein:
at least one of the beamsplitter metalens, the first metalens, or the second metalens are deposited on a substrate layer, and
a refractive index of the beamsplitter metalens, the first metalens, or the second metalens is higher than a refractive index of the substrate layer.

13. The polarization filter of claim 1, wherein a nanostructure element of at least one of the beamsplitter metalens, the first metalens, or the second metalens may be configured with at least one of a circle, an oval, a square, a rectangle, a triangle, a pillar, a hole, or an anisotropic geometry.

14. The polarization filter of claim 1, wherein the first polarized state and the second polarized state comprise, respectively, a first linear polarization and a second linear polarization, or a first circular polarization and a second circular polarization.

15. The polarization filter of claim 1, wherein:
the beamsplitter metalens is configured to cause a first steering on the beam of light of the first polarized state and cause a second steering on the beam of light of the second polarized state,
the first metalens is configured to cause a third steering on the beam of light of the first polarized state, and
the first metalens is configured to cause a fourth steering on the beam of light of the second polarized state.

16. The polarization filter of claim 15, wherein:
the first steering includes at least one of focusing, bending, or passing the beam of light of the first polarized state,
the second steering includes at least one of focusing, bending, or passing the beam of light of the second polarized state,
the third steering includes at least one of focusing, bending, or passing the beam of light of the first polarized state, and
the fourth steering includes at least one of focusing, bending, or passing the beam of light of the second polarized state.

17. A method comprising:
splitting, via a beamsplitter metalens, incident light that is unpolarized into a beam of light of a first polarized state and a beam of light of a second polarized state;
deflecting, via a first metalens, the beam of light of the first polarized state received from the beamsplitter metalens;
deflecting, via a second metalens adjacent to the first metalens, the beam of light of the second polarized state received from the beamsplitter metalens;
converting, via the second metalens, a polarization of the beam of light of the second polarized state in conjunction with the deflecting via the second metalens; and
receiving, via a beam receiving element, a combination of the deflected light of the first polarized state from the first metalens and the deflected converted light of the second polarized state from the second metalens, the beam receiving element comprising at least one of a photodetector, a curved lens, a metalens, a nanostructure, or a mirror.

18. The method of claim 17, wherein the second metalens is configured to convert the beam of light of the second polarized state from the second polarized state to the first polarized state.

19. A polarization sensor, comprising:
a beamsplitter metalens to split incident light that is unpolarized into a beam of light of a first polarized state and a beam of light of a second polarized state;
a first metalens to deflect the beam of light of the first polarized state received from the beamsplitter metalens;
a second metalens adjacent to the first metalens, the second metalens to deflect the beam of light of the second polarized state received from the beamsplitter metalens and to convert a polarization of the beam of light of the second polarized state; and
a photodetector to detect a combination of the deflected light of the first polarized state from the first metalens and the deflected converted light of the second polarized state from the second metalens.

20. The polarization sensor of claim 19, wherein the second metalens is configured to convert the beam of light of the second polarized state from the second polarized state to the first polarized state.
